(19) United States
(12) Patent Application Publication
(10) Pub. No.: US 2017/0345722 A1
(43) Pub. Date: Nov. 30, 2017

(54) HIGH-K METAL GATE DEVICE AND MANUFATURING METHOD THEREOF

(71) Applicant: Shanghai Huali Microelectronics Corporation, Shanghai (CN)

(72) Inventors: Zhibin He, Shanghai (CN); Xubin Jing, Shanghai (CN)

(21) Appl. No.: 15/235,155

(22) Filed: Aug. 12, 2016

(30) Foreign Application Priority Data
May 30, 2016 (CN) 201610367945.6

(51) Int. Cl. H01L 21/8238; H01L 27/092; H01L 21/324; H01L 29/51; H01L 29/423

(52) U.S. Cl. CPC H01L 21/823857; H01L 29/518; H01L 29/4236; H01L 21/324; H01L 21/823828; H01L 27/092

(57) ABSTRACT

A high-k metal gate device and manufacturing method thereof are provided in the present invention. The method uses a silicon material layer as a battier layer for the lower silicon nitride layer in the NMOS region and then performs an annealing process to turn the silicon material layer into a TiSiN interlayer of the PMOS region and a TiSiN layer of the NMOS region, respectively. TiSiN material can prevent subsequent upper metal atoms from diffusing downward and improve the stability of the metal gate device. Additionally, the silicon material remained on the surface of the NMOS region is subsequently removed, thereby eliminating differences of the thickness of the residual silicon material layer and fluctuations of the threshold voltage of the NMOS region resulted from the differences thereof and further improving the stability of the NMOS device.

### CROSS-REFERENCES TO RELATED APPLICATIONS

This application claims the priority benefit of Chinese patent application number 201610367945.6, filed on 30 May 2016, the entire contents of which are incorporated herein by reference.

### FIELD OF THE INVENTION

The present invention relates to the field of semiconductor manufacturing technology, and more particularly to a high-k metal gate device and a manufacturing method thereof.

### BACKGROUND OF THE INVENTION

With the rapid development of VLSI (Very Large Scale integration) technology, the size of the MOSFET devices continue to be reduced, usually including the decrease of the MOSFET device channel length, the decrease of the MOSFET device gate oxide thickness thinning, etc., in order to obtain a high-speed device. However, when the dimension of the MOSFET decreases to ultra-deep sub-micrometer level, particularly to 45 nm and below technology nodes, continuous reduction in the thickness of the gate oxide layer will result in high leakage currents. Therefore, high k dielectric layers and metal gates have been introduced into the design processes at 45 nm and below.

In the field of the high-k metal gate semiconductor technology, a tantalum nitride (TaN) layer is usually chosen as a P-type work function layer in NMOS regions and also as an etch stop layer for removing TiN. However, the small difference of the TiN etching process will result in fluctuations of the thickness of the residual TaN etch stop layer and finally be reflected in the threshold voltage of the NMOS metal gate device. In addition, when the TaN layer is used as a work function interlayer of PMOS regions, the lattice structure determines that, under a certain thermodynamic condition, the TaN layer cannot be an effective barrier against the diffusion behavior of the upper and lower metal element, therefore, the stability of the high-k metal gate PMOS device is not desirable.

### BRIEF SUMMARY OF THE DISCLOSURE

Accordingly, at least one object of the present invention is to provide a high-k metal gate device and a manufacturing method thereof.

To achieve above object or another, the present invention provides a high-k metal gate device; the high-k metal gate device comprises an NMOS region and a PMOS region, which are disposed in parallel on a silicon substrate; the NMOS region has a first trench in the silicon substrate and the PMOS region has a second trench in the silicon substrate, respectively; a high-k dielectric layer and a lower titanium nitride layer are formed sequentially in both the first trench and the second trench; wherein, in the first trench, a TiSiN layer is formed on the surface of the lower titanium nitride layer; in the second trench, an upper titanium nitride layer and a TiSiN interlayer are formed sequentially on the lower titanium nitride layer; the TiSiN layer is used as a diffusion barrier in the NMOS region and the TiSiN interlayer is used as another diffusion barrier in the PMOS region.

Preferably, the TiSiN layer is in an amorphous state; the TiSiN interlayer is in an amorphous state.

Preferably, the thickness of the TiSiN interlayer is larger than that of the TiSiN layer.

Preferably, the thickness of the TiSiN layer is in the range of 2 to 80 Å and thickness of the TiSiN interlayer is in the range of 2 to 80 Å.

Preferably, the upper titanium nitride layer is used as a P-type work function layer of the PMOS region.

Preferably, an N-type work function layer and a metal gate layer are formed sequentially on the TiSiN layer of the first trench and the upper titanium nitride layer of the second trench.

To achieve above object or another, the present invention also provides a method for manufacturing the high-k metal gate device as mentioned above, which including the following steps:
step 01: providing a silicon substrate; wherein the silicon substrate comprises a NMOS region and a PMOS region disposed in parallel on the silicon substrate; forming a first trench in the NMOS region and forming a second trench in the PMOS region, respectively; then, forming a high-k dielectric layer and a lower titanium nitride layer sequentially in both the first trench and the second trench;
step 02: forming a silicon material layer on the lower titanium nitride layer;
step 03: forming an upper titanium nitride layer on the silicon material layer;
step 04: removing the upper titanium nitride layer of the first trench;
step 05: performing an annealing process, whereby making the silicon of the silicon material layer diffuse into the upper titanium nitride layer and the lower titanium nitride layer, in order to form a TiSiN layer on the lower titanium nitride layer in the first trench and form a TiSiN interlayer between the lower titanium nitride layer and the upper titanium nitride layer in the second trench;
step 06: removing the residual silicon material layer of the NMOS region.

Preferably, in step 02, the silicon material layer is formed on the lower titanium nitride layer by an atom deposition process.

Preferably, after step 06, further including: depositing an N-type work function layer and a metal gate sequentially on the upper titanium nitride layer and the TiSiN layer.

Preferably, in step 05, an annealing temperature for the annealing process is in a range of 50 to 1250° C. and an annealing time interval for the annealing process is in a range of 0.1 to 1000 second.

Preferably, in step 06, a tetramethylammonium hydroxide is used for removing the residual silicon material layer in the NMOS region.

Preferably, the thickness of the TiSiN interlayer is more than that of the TiSiN layer.

The high-k metal gate device and the manufacturing method thereof according to the present invention including: using the silicon material layer as a battier layer for the lower silicon nitride layer of the NMOS region, and then performing the annealing process to make the silicon diffuse sufficiently into the upper silicon nitride layer and the lower silicon nitride layer, in order to form the TiSiN interlayer of the PMOS region and the TiSiN layer of the NMOS region, respectively. TiSiN material can prevent subsequent upper metal atoms from diffusing downward and improve the stability of the metal gate device. In addition, the silicon material remained on the surface of the NMOS region is removed subsequently, thereby eliminating differences of the thickness of the residual silicon material layer and fluctuations of the threshold voltage of the NMOS region resulted from the differences thereof and further improving the stability of the NMOS device, and furthermore, the stability of the whole high-k metal gate device is improved.

### BRIEF DESCRIPTION OF THE DRAWINGS

FIG. 1 is an structural view of the high-k metal gate device according to one embodiment of the present invention;

FIG. 2 is a flow chart of the method of manufacturing the high-k metal gate device according to one embodiment of the present invention;

FIGS. 3 to 8 are views illustrating each step in the method of manufacturing the high-k metal gate device according to one embodiment of the present invention.

### DETAILED DESCRIPTION

The present invention will now be descried more comprehensively hereinafter with reference to the accompanying drawings, in which preferred embodiments of the invention are shown. This invention may, however, be embodied in different forms and should not be construed as limited to the embodiments set forth herein.

The high-k metal gate device and the manufacturing method thereof according to the present invention will be described in further detail hereinafter with the embodiments. It is noted that the drawings are not necessarily to scale, emphasis instead being placed upon illustrating the principles of the present invention.

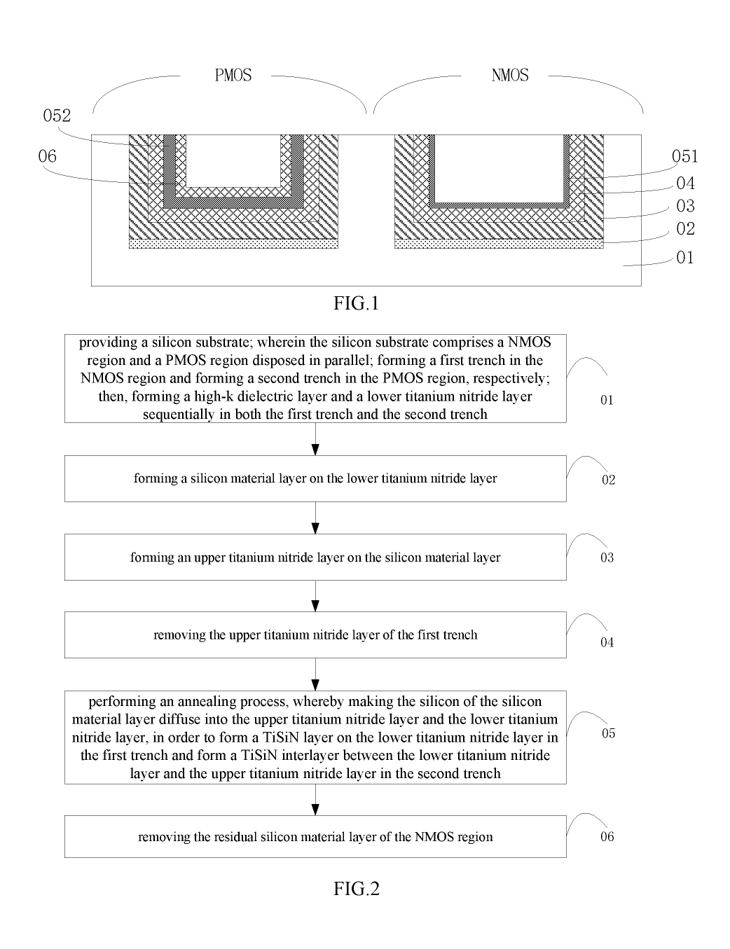

Please referring to FIG. 1, the high-k metal gate device of the embodiment comprises an NMOS region and a PMOS region disposed in parallel on a silicon substrate 01; the NMOS region has a first trench and the PMOS region has a second trench, respectively. An oxide layer 02 is formed at the bottom of the first trench and the second trench; a high-k dielectric layer 03 is deposited on the oxide layer 02 and on the sidewalls of the first trench and the second trench; a lower titanium nitride layer 04 is formed on the surface of the high-k dielectric layer 03.

A TiSiN layer 051 is formed on the surface of the lower titanium nitride layer 04 in the first trench; a TiSiN interlayer 052 is formed on the lower titanium nitride layer 04 of the second trench; an upper titanium nitride layer 06 is formed on the TiSiN interlayer 052. In the embodiment, the upper titanium nitride layer 06 is used a P-type work function layer of the PMOS region; an N-type work function layer and a metal gate layer are formed sequentially on the upper titanium nitride layer 06 of the PMOS region and the TiSiN layer 051 of the NMOS region.

In the embodiment, the TiSiN layer is used as a diffusion barrier in the NMOS region and the TiSiN interlayer is used as another diffusion barrier in the PMOS region. Herein the TiSiN layer 051 and the TiSiN interlayer 052 are in an amorphous state. The thickness of the TiSiN interlayer 052 is larger than that of the TiSiN layer 051; preferably, the thickness of the TiSiN layer 051 is in the range of 2 to 80 Å and thickness of the TiSiN interlayer 052 is in the range of 2 to 80 Å. The amorphous TiSiN layer 051 and the amorphous TiSiN interlayer 052 have little work function fluctuations and can prevent the subsequent metal atom from diffusing downward, so as to improve the stability of the NMOS device and the PMOS device. Additionally, the material of the high-k dielectric layer 03 is HfO₂.

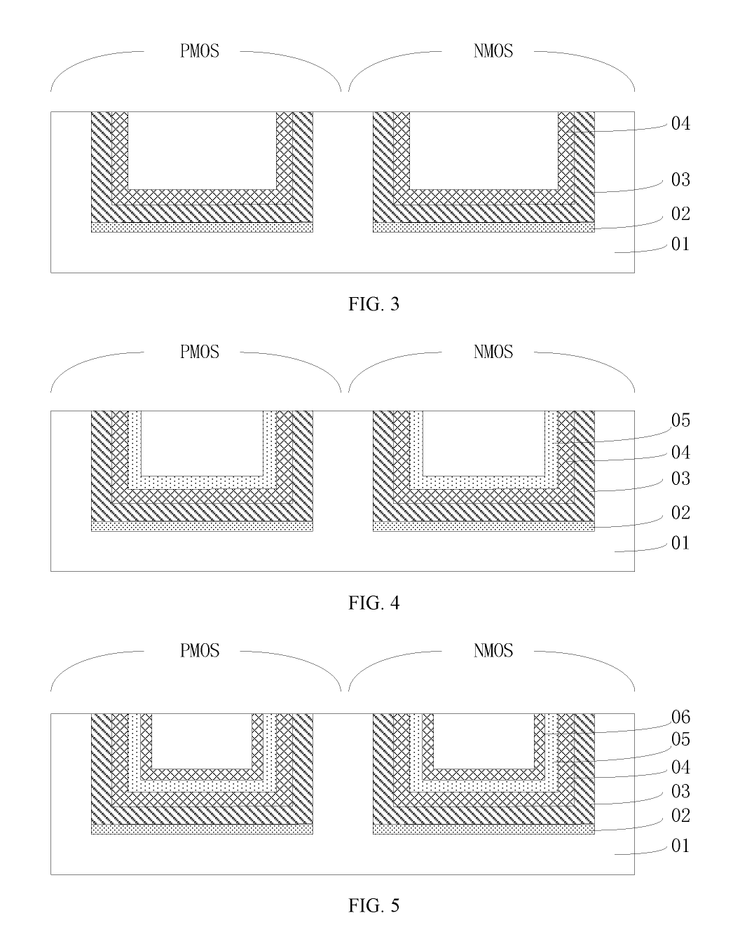

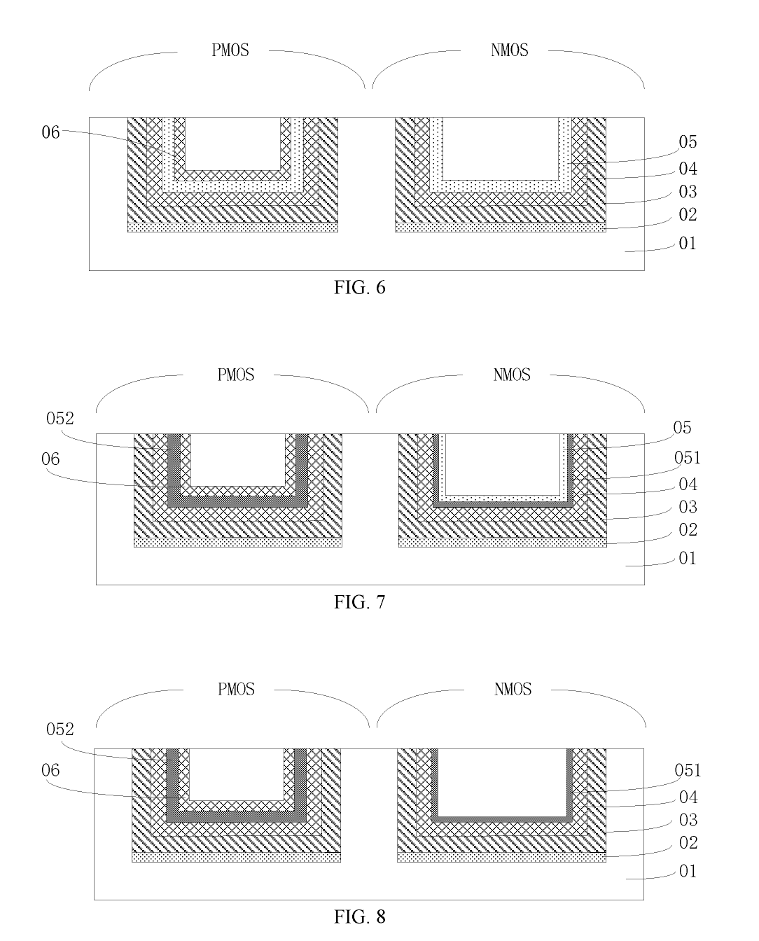

The present invention further provides a method for manufacturing the high-k metal gate device as mentioned above, please referring to FIG. 2, which including the following steps:
step 01: providing a silicon substrate; wherein the silicon substrate comprises a NMOS region and a PMOS region disposed in parallel; forming a first trench in the NMOS region and forming a second trench in the PMOS region, respectively; then, forming a high-k dielectric layer and a lower titanium nitride layer sequentially in both the first trench and the second trench;
specifically, please referring to FIG. 3, firstly, the first trench and the second trench are formed separately in the PMOS region and the NMOS region simultaneously; next, an oxide layer 02 is formed at the bottom of the first trench and the second trench simultaneously; then, the high-k dielectric layer 03 is formed on the oxide layer 02 and the sidewalls of the first trench and the second trench simultaneously; finally, the lower titanium nitride layer 04 is formed on the surface of the high-k dielectric layer 03 in the first trench and the second trench simultaneously, which is a conventional process and will not be repeated herein. Additionally, the material of the high-k dielectric layer 03 is HfO₂.
step 02: forming a silicon material layer on the lower titanium nitride layer;
specifically, please referring to FIG. 4, the silicon material layer 05 is deposited on the lower titanium nitride layer 04 of the PMOS region and the NMOS region simultaneously by atomic layer deposition, which is used as a barrier layer in the step 04 and a sacrificial layer in the step 05.
step 03: forming an upper titanium nitride layer on the silicon material layer;
specifically, please referring to FIG. 5, herein the upper titanium nitride layer 06 is used as a P-type work function layer of the PMOS region; the deposition of the upper titanium nitride layer 06 can be realized by a conventional process, which will not be repeated herein.
step 04: removing the upper titanium nitride layer of the first region;
specifically, please referring to FIG. 6, lithography and etching processes are used to remove the upper titanium nitride layer 06 in the first trench and the etching process stops at the surface of the silicon material layer 05 in the first trench.
step 05: performing an annealing process, whereby making the silicon of the silicon material layer diffuse into the upper titanium nitride layer and the lower titanium nitride layer, in order to form a TiSiN layer on the surface of the lower titanium nitride layer in the first trench and form a TiSiN interlayer between the lower titanium nitride layer and the upper titanium nitride layer in the second trench.
specifically, please referring to FIG. 7, the annealing process can make the silicon material layer 05 fully diffuse. In the PMOS region, the silicon atoms of the silicon material layer 05 diffuse fully into the upper titanium nitride layer 06 and the bottom titanium nitride layer 04 to form TiSiN material together with the titanium nitride both in the upper titanium nitride layer 06 and the bottom titanium nitride layer 04, so as to form the TiSiN interlayer 052 between the upper titanium nitride layer 06 and the bottom titanium nitride layer 04; in the NMOS region, the silicon material layer 05 and the lower titanium nitride layer 04 diffuse fully into each other, the silicon and the titanium nitride react together to form TiSiN material, so as to form the TiSiN layer 051 on the surface of the lower titanium nitride layer 04. Preferably, the annealing temperature for the annealing process is in a range of 50 to 1250° C., such as, in a range of 50 to 120° C.; the annealing time interval for the annealing process is in a range of 0.1 to 1000 second. The thickness of the TiSiN interlayer 052 is more than that of the TiSiN layer 051, preferably, the thickness of the TiSiN layer 051 is 2 to 80 Å and thickness of the TiSiN interlayer 052 is 2 to 80 Å. It is noted that, since there is no upper titanium nitride layer 06 on the silicon material layer 05 in the NMOS region, the silicon material layer 05 is still remained on the surface of the TiSiN layer 051 after the annealing process, which should be removed subsequently, in order to avoid the stability of the NMOS device being influenced by the thickness difference resulted from the residual silicon material layer 05 on the TiSiN layer 051.
step 06: removing the residual silicon material layer of the NMOS region.
Specifically, please referring to FIG. 8, a tetramethylammonium hydroxide is used for removing the residual silicon material layer in the NMOS region. The concentration of the tetramethylammonium hydroxide is in the range of 1% to 20% and the temperature used is in the range of 5 to 50° C.

In the embodiment, after the step 06 further including steps such as forming an N-type work function layer on the TiSiN layer of the first trench and on the upper titanium nitride layer of the second trench, then forming a metal gate on the N-type work function layer, which will not be repeated herein.

While this invention has been particularly shown and described with references to preferred embodiments thereof, if will be understood by those skilled in the art that various changes in form and details may be made herein without departing from the spirit and scope of the invention as defined by the appended claims.

1. A high-k metal gate device, wherein, comprising an NMOS region and a PMOS region disposed in parallel on a silicon substrate; the NMOS region has a first trench in the silicon substrate and the PMOS region has a second trench in the silicon substrate, respectively; a high-k dielectric layer and a lower titanium nitride layer are formed sequentially in both the first trench and the second trench; wherein, in the first trench, a TiSiN layer is formed on the surface of the lower titanium nitride layer; in the second trench, an upper titanium nitride layer and a TiSiN interlayer are formed sequentially on the lower titanium nitride layer; the TiSiN layer is used as a diffusion barrier in the NMOS region and the TiSiN interlayer is used as another diffusion barrier in the PMOS region.

2. The high-k metal gate device according to claim 1, wherein, the TiSiN layer is in an amorphous state; the TiSiN interlayer is in an amorphous state.

3. The high-k metal gate device according to claim 1, wherein, the thickness of the TiSiN interlayer is larger than that of the TiSiN layer.

4. The high-k metal gate device according to claim 3, wherein, the thickness of the TiSiN layer is in the range of 2 to 80 Å and thickness of the TiSiN interlayer is in the range of 2 to 80 Å.

5. The high-k metal gate device according to claim 1, wherein the upper titanium nitride layer is used as a P-type work function layer of the PMOS region.

6. The high-k metal gate device according to claim 1, wherein, an N-type work function layer and a metal gate layer are formed sequentially on the TiSiN layer of the first trench and the upper titanium nitride layer of the second trench.

7. A method of manufacturing the high-k metal gate device according to claim 1, wherein, comprising the following steps:
step 01: providing a silicon substrate; wherein the silicon substrate comprises a NMOS region and a PMOS region disposed in parallel on the silicon substrate; forming a first trench in the NMOS region and forming a second trench in the PMOS region, respectively; then, forming a high-k dielectric layer and a lower titanium nitride layer sequentially in both the first trench and the second trench;
step 02: forming a silicon material layer on the lower titanium nitride layer;
step 03: forming an upper titanium nitride layer on the silicon material layer;
step 04: removing the upper titanium nitride layer of the first trench;
step 05: performing an annealing process, whereby making the silicon of the silicon material layer diffuse into the upper titanium nitride layer and the lower titanium nitride layer, in order to form a TiSiN layer on the lower titanium nitride layer in the first trench and form a TiSiN interlayer between the lower titanium nitride layer and the upper titanium nitride layer in the second trench;
step 06: removing the residual silicon material layer of the NMOS region.

8. The method for manufacturing the high-k metal gate device according to claim 7, wherein, in step 02, the silicon material layer is formed on the lower titanium nitride layer by an atom deposition process.

9. The method for manufacturing the high-k metal gate device according to claim 7, wherein, after step 06, further including: depositing an N-type work function layer and a metal gate sequentially on the upper titanium nitride layer and the TiSiN layer.

10. The method for manufacturing the high-k metal gate device according to claim 7, wherein, in step 05, an annealing temperature for the annealing process is in a range of 50 to 1250° C. and an annealing time interval for the annealing process is in a range of 0.1 to 1000 second.

11. The method for manufacturing the high-k metal gate device according to claim 7, wherein, in step 06, a tetramethylammonium hydroxide is used for removing the residual silicon material layer in the NMOS region.

12. The method for manufacturing the high-k metal gate device according to claim 7, wherein, the thickness of the TiSiN interlayer is more than that of the TiSiN layer.
